(19) United States
(12) Patent Application Publication
(10) Pub. No.: US 2022/0270921 A1
(43) Pub. Date: Aug. 25, 2022

(54) METHOD FOR FORMING SEMICONDUCTOR STRUCTURE AND SEMICONDUCTOR STRUCTURE

(71) Applicant: CHANGXIN MEMORY TECHNOLOGIES, INC., Hefei City (CN)

(72) Inventor: Xingrun REN, Hefei (CN)

(73) Assignee: CHANGXIN MEMORY TECHNOLOGIES, INC., Hefei City (CN)

(21) Appl. No.: 17/445,675

(22) Filed: Aug. 23, 2021

Related U.S. Application Data
(63) Continuation of application No. PCT/CN2021/103038, filed on Jun. 29, 2021.

(30) Foreign Application Priority Data
Feb. 23, 2021 (CN) 202110200555.0

(51) Int. Cl. H01L 21/768; H01L 23/532

(52) U.S. Cl. CPC H01L 21/76829; H01L 23/53238; H01L 23/53223; H01L 23/5329; H01L 21/76877; H01L 21/76843

(57) ABSTRACT

A method for forming a semiconductor structure includes: providing a substrate; forming a plurality of first barrier structures that are distributed at intervals on the substrate, in which first trench structures exposing the substrate is provided between the adjacent first barrier structures; forming an initial dielectric layer, in which the initial dielectric layer fills up the first trench structure; removing part of the initial dielectric layer to form a dielectric layer which has second trench structures exposing part of the first barrier structures, in which a compactness of a material forming the first barrier structure is larger than that of a material forming the dielectric layer; and forming a conductive layer which fills up the second trench structures.

### CROSS-REFERENCE TO RELATED APPLICATIONS

This is a continuation of International Application No. PCT/CN2021/103038 filed on Jun. 29, 2021, which claims priority to Chinese Patent Application No. 202110200555.0 filed on Feb. 23, 2021. The disclosures of these applications are hereby incorporated by reference in their entirety.

### BACKGROUND

As integration level of semiconductor devices becomes higher and higher, circuit sizes become smaller accordingly, and depths of conductive contact structures needed inside semiconductor devices gradually increase. A current density in a conductive structure such as a plug wire increases, and a traditional plug wire structure is undergoing a huge challenge.

### SUMMARY

This application relates to the field of semiconductor manufacturing technology, in particular to a method for forming a semiconductor structure and a semiconductor structure.

This disclosure provides a method for forming a semiconductor structure. The method includes operations as follow.

A substrate is provided.

A plurality of first barrier structures that are distributed at intervals on the substrate are formed, in which first trench structures exposing the substrate are provided between the adjacent first barrier structures.

An initial dielectric layer which fills up the first trench structures is formed.

Part of the initial dielectric layer is removed to form a dielectric layer which has second trench structures that expose part of the first barrier structures, in which a compactness of a material of forming the first barrier structures is larger than that of a material forming the dielectric layer.

A conductive layer which fills up the second trench structures is formed.

This disclosure also provides a semiconductor structure, which includes a substrate, first barrier structures, a dielectric layer and a conductive layer.

The first barrier structures are distributed at intervals on the substrate, first trench structures exposing the substrate are provided between the adjacent first barrier structures.

The dielectric layer which fills up at least part of the first trench structures has second trench structures, and the second trench structures expose part of the first barrier structures, in which a compactness of a material forming the first barrier structures is larger than that of a material forming the dielectric layer.

The conductive layer fills up the second trench structures.

### BRIEF DESCRIPTION OF THE DRAWINGS

FIG. 1 is a flowchart of a method for forming a semiconductor structure in an implementation of this disclosure.

FIG. 2A is a first schematic cross-section view of main processes in formation of a semiconductor structure in an implementation of this disclosure.

FIG. 2B is a second schematic cross-section view of main processes in formation of a semiconductor structure in an implementation of this disclosure.

FIG. 2C is a third schematic cross-section view of main processes in formation of a semiconductor structure in an implementation of this disclosure.

FIG. 2D is a fourth schematic cross-section view of main processes in formation of a semiconductor structure in an implementation of this disclosure.

FIG. 2E is a fifth schematic cross-section view of main processes in formation of a semiconductor structure in an implementation of this disclosure.

FIG. 2F is a sixth schematic cross-section view of main processes in formation of a semiconductor structure in an implementation of this disclosure.

FIG. 2G is a seventh schematic cross-section view of main processes in formation of a semiconductor structure in an implementation of this disclosure.

FIG. 2H is an eighth schematic cross-section view of main processes in formation of a semiconductor structure in an implementation of this disclosure.

FIG. 2I is a ninth schematic cross-section view of main processes in formation of a semiconductor structure in an implementation of this disclosure.

FIG. 2J is a tenth schematic cross-section view of main processes in formation of a semiconductor structure in an implementation of this disclosure.

### DETAILED DESCRIPTION

Implementations of a method for forming a semiconductor structure and a semiconductor structure provided in this disclosure are illustrated in detail in conjunction with drawings.

In a typical plug wire manufacturing process, conductive materials most commonly used for forming plug wires include metal Cu and metal Al. Correspondingly, materials of wire barrier layers usually include Ta, Ru and Ti. In a traditional wire manufacturing process, a dielectric layer is usually etched through a dry etching process to form through holes, then a barrier layer is deposited in the through hole, and finally a metal wire is deposited in the through hole. However, in the prior art, silica is usually used as the dielectric layer. However, due to compactness of the silica material, corners of through holes will be damaged during the process of forming the through holes via an etching process. Subsequent cleaning of the etched structure by wet etching will further aggravate the damage to the corners. Moreover, when using the semiconductor device, plug wires are eroded by current for a long time, and electric leakage occurs at the corners of the plug wires so as to cause the diffusion of metal ions, affecting the service life of the device, and even leading to the failure of the device in severe cases. In addition, generally materials with a higher compactness have a larger dielectric constant (e.g., the compactness of silicon nitride is very well, but the dielectric constant of silicon nitride is much larger than that of silica). Simply replacing the dielectric layer with a material with a higher compactness can lead to a large parasitic capacitance between wire structures, which can seriously affect the performance of the semiconductor device.

As electronic products such as cell phones are more and more widely used in people's daily life, the strength of operation of memory chips or logic chips inside the electronic products has increased geometrically. Various embodiments of the present disclosure address a technical problem of how to improve the stability of a plug wire so as to enhance the reliability of the semiconductor.

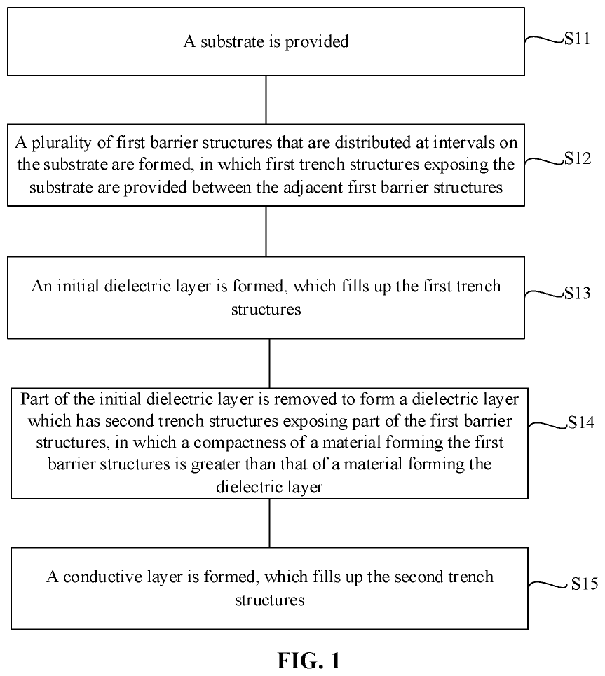

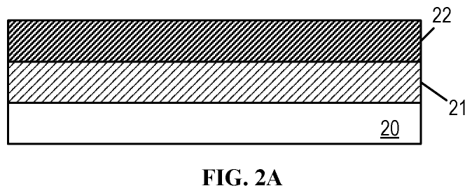

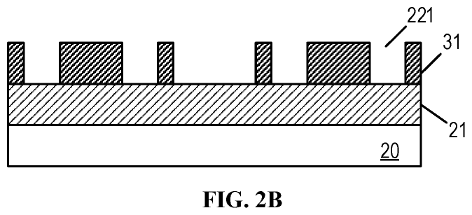

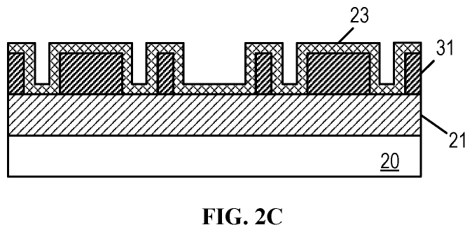

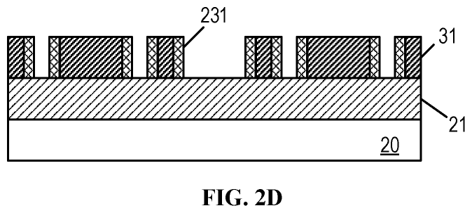

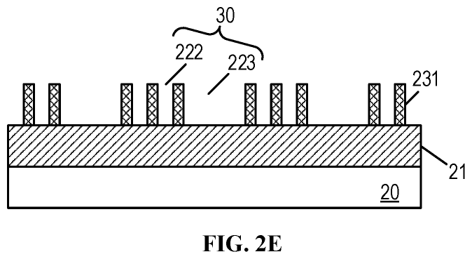

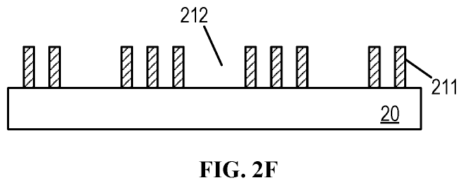

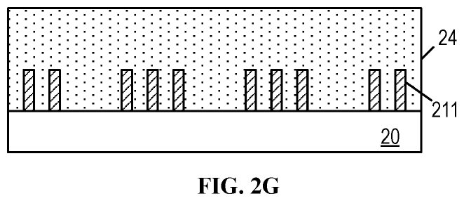

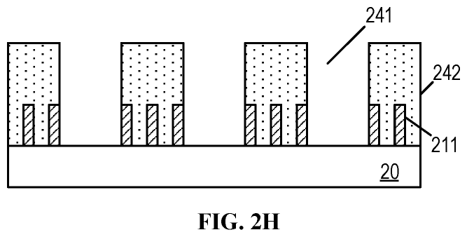

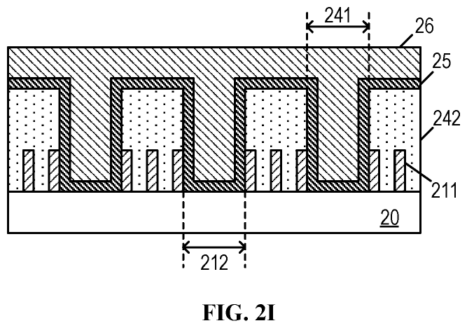

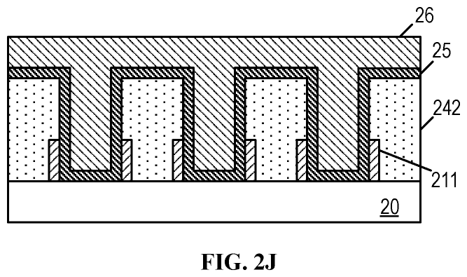

Various embodiments of the present disclosure provide a method for forming a semiconductor structure. FIG. 1 is a flowchart of a method for forming a semiconductor structure in an implementation of this disclosure. FIGS. 2A-2J are schematic cross-section views of main processes in the method of forming a semiconductor structure in the implementation of this disclosure. The semiconductor structure described in the implementation may be but is not limited to a dynamic random access memory (DRAM). As shown in FIG. 1, FIG. 2A-FIG. 2J, the method for forming the semiconductor structure provided in the implementation includes the following steps.

At S11, a substrate 20 is provided.

Specifically, the substrate 20 may be but is not limited to a silicon substrate or a polycrystalline silicon substrate. In the implementation, the substrate 20 being a silicon substrate is taken as an example. The substrate 20 is configured to support a device structure thereon. In other examples, the substrate 20 may be a gallium nitride semiconductor substrate, a gallium arsenide semiconductor substrate, a gallium carbide semiconductor substrate, a silicon carbide semiconductor substrate, an SOI semiconductor substrate, or the like. The substrate 20 may be a single-layer substrate or a multi-layer substrate formed by a plurality of semiconductor layers that are superposed, and those skilled in the art can select according to actual needs. The substrate 20 can also be internally provided with an active region, a transistor, a shallow trench isolation structure, a word line, and other structures.

At S12, a plurality of first barrier structures 211 that are distributed at intervals are formed on the substrate 20. First trench structures 212 exposing the substrate 20 is provided between the adjacent first barrier structures 211, as shown in FIG. 2F.

Optionally, the specific step of forming a plurality of first barrier structures 211 that are distributed at intervals on the substrate 20 includes the following.

A first barrier layer 21 is formed on the substrate 20, and the first barrier layer 21 covers the substrate 20, as shown in FIG. 2A.

A dielectric layer 231 is formed on the first barrier layer 21, the dielectric layer 231 has third trench structures 30, and projections of the third trench structures 30 on the substrate 20 coincides with projections of the first trench structures 212 on the substrate 20, as shown in FIG. 2E.

The first barrier layer 21 is etched by adopting the dielectric layer 231 as a mask, as shown in FIG. 2F.

The dielectric layer 231 is removed.

Specifically, after forming the substrate 20, the first barrier layer 21 may be deposited on a surface of the substrate 20 by adopting a chemical vapor deposition process, a physical vapor deposition process, or an atomic layer deposition process, with the first barrier layer 21 covering the surface of the substrate 20. Afterwards, the dielectric layer 231 is formed on a surface of the first barrier layer 21 according to the shape of the first barrier structures 211 to be formed and the shape of the first trench structures 212 adjacent to the first barrier structures 211, and the dielectric layer 231 has third trench structures 30 inside as shown in FIG. 2E. The projections of the third trench structures 30 in a direction perpendicular to the substrate 20 coincides with the projections of the ultimately to be formed first trench structures 212 in a direction perpendicular to the substrate 20. After forming the dielectric layer 231 having the third trench structures 30, the first barrier layer 21 is patterned by etching and the like by adopting the dielectric layer 231 as the mask. A plurality of first trench structures 212 running through the first barrier layer 21 in the direction perpendicular to the substrate 20 is formed in the first barrier layer 21, and the plurality of the first trench structures 212 divide the remaining first barrier layer 21 into a plurality of first barrier structures 211. The “plurality” described in the implementation refers to two and more. The plurality of first barrier structures 211 that are distributed at intervals means that any two of the first barrier structures 211 are physically isolated from each other (i.e., any two of the first barrier structures 211 that are adjacent have one first trench structure 212 therebetween). That is, any two of the first barrier structures 211 are not connected with each other.

The implementation is illustrated by the plurality of third trench structures 30 with different widths in the dielectric layer 231 (e.g., the third trench structures 30 described in FIG. 2E includes a first sub-trench structure 222 and a second sub-trench structure 223 with different widths). Those skilled in the art may also set widths of all the third trench structures 30 in the dielectric layer to be the same. In the implementation, the width of a third trench structure 30 refers to an inner diameter of the third trench structure 30.

Optionally, the specific step that forming a dielectric layer 231 on the first barrier layer 21 includes the following operations.

An initial mask layer 22 is formed on the first barrier layer 21, and the initial mask layer 22 covers the first barrier layer 21, as shown in FIG. 2A.

The initial mask layer 22 is patterned to form a mask layer 31, and the mask layer 31 has fourth trench structures 221, as shown in FIG. 2B.

An initial dielectric layer 23 is formed, and the initial dielectric layer 23 covers at least bottoms and sidewalls of the fourth trench structures 221, as shown in FIG. 2C.

The mask layer 31 and part of the initial dielectric layer 23 are removed, and the initial dielectric layer 23 covering the sidewalls of the fourth trench structures 221 are remained to serve as the dielectric layer 231, as shown in FIG. 2E.

Optionally, the operation of forming the initial dielectric layer 23 that covering at least bottoms and sidewalls of the fourth trench structures 221 includes the following operations.

The initial dielectric layer 23 is formed by adopting atomic layer deposition (ADL). The atomic layer deposition process can control the uniformity of a deposited film well compared to other deposition processes. The formation of the initial dielectric layer 23 by the atomic layer deposition method can ensure that a thickness of the initial dielectric layer 23 is uniform, thus ensuring the stability of the subsequently formed semiconductor structure.

For example, after forming the first barrier layer 21 on the surface of the substrate 20, the initial mask layer 22 is deposited on the surface of the first barrier layer 21 such that the initial mask layer 22 completely covers the first barrier layer 21, as shown in FIG. 2A. A material of the initial mask layer 22 may be an organic mask material, such as SOC, and may also be a hard mask material, such as polycrystalline silicon. The initial mask layer 22 can be formed on the surface of the first barrier layer 21 by the chemical vapor deposition process or the atomic layer deposition process. Afterwards, the initial mask layer 22 is patterned, i.e., the initial mask layer 22 is etched by adopting a dry etching process or a wet etching process, so as to form the fourth trench structures 221 in the initial mask layer 22 along the direction perpendicular to the substrate 20 through the initial mask layer 22, the mask layer 31 is formed, as shown in FIG. 2B.

Next, a silica material or the like is deposited by adopting an atomic layer deposition process to form the initial dielectric layer 23 covering inner walls of the fourth trench structures 221 (including the bottom and sidewalls of the fourth trench structures 221) and top surfaces of the mask layer 31 (i.e., the surface of the mask layer 31 facing away from the substrate 20), as shown in FIG. 2C. The initial dielectric layer 23 formed by adopting the atomic layer deposition process has better uniformity, which ensures the uniformity of morphology of the first barrier structures 211 formed subsequently. In order to facilitate subsequent selective removal of the mask layer 31, there should be a high etch selectivity ratio between the material of the mask layer 31 and the material of the initial dielectric layer 23. For example, an etch selectivity ratio between the mask layer 31 and the initial dielectric layer 23 is larger than 3 (e.g., an etch selectivity ratio may be 5). Then, the initial dielectric layer 23 covering the top surface of the mask layer 31 and the bottom of the fourth trench structures 221 is removed by etching or the like. Only the initial dielectric layer 23 covering the sidewalls of the fourth trench structures 221 remains, and the initial dielectric layer 23 covering the sidewalls of the fourth trench structures 221 is used as the dielectric layer 231, as shown in FIG. 2D. Afterwards, the whole mask layer 31 is cleaned by a wet etching process or removed by a dry etching process with a higher directionality, thus the third trench structures 30 are formed as shown in FIG. 2E. The third trench structures 30 include a first sub-trench structure 222 and a second sub-trench structure 223. The first sub-trench structure 222 and the second sub-trench structure 223 may have a same width, or different widths. Herein, the first sub-trench structure 222 is formed after forming the dielectric layer 231 and formed at the location where the residual mask layer 31 is removed. The second sub-trench structure 223 is also formed after forming the dielectric layer 231 and formed at the location of the fourth trench structures 221. In the structure shown in FIG. 2E, the first sub-trench structures 222 and the second sub-trench structures 223 are arranged alternately along a direction parallel to the surface of the substrate 20.

Next, the first barrier layer 21 is etched by adopting the dry etching process along the first sub-trench structure 222 and the second sub-trench structure 223 to form a plurality of first trench structures 212 running through the first barrier layer 21 in the direction perpendicular to the substrate 20 in the first barrier layer 21, with the residual first barrier layer 21 serving as the first barrier structures 211, as shown in FIG. 2F.

At S13, an initial dielectric layer 24 is formed, and the initial dielectric layer 24 fully fills the first trench structures 212.

At S14, part of the initial dielectric layer 24 is removed to form a dielectric layer 242. The dielectric layer 242 has second trench structures 241. The second trench structures 241 expose part of the first barrier structures 211. In addition, the compactness of a material forming the first barrier structures 211 is larger than that of a material forming the dielectric layer 242, as shown in FIG. 2H.

Specifically, after forming the first barrier structures 211 and the first trench structures 212 located between the adjacent first barrier structures 211, a material such as silica is deposited by adopting the chemical vapor deposition process, the initial dielectric layer 24 that fully fills all the first trench structures 212 is formed and completely covers top surfaces of all the first barrier structures 211 (i.e., the surfaces of the first barrier structures 211 facing away from the substrate 20), as shown in FIG. 2G. Afterwards, part of the initial dielectric layer 24 is etched by adopting the dry etching process to form second trench structures 241 running through the initial dielectric layer 24 in the direction perpendicular to the substrate 20, and the second trench structures 241 divides the initial dielectric layer 24 into a plurality of dielectric layers 242, as shown in FIG. 2H.

According to the implementation, by defining the compactness of the material forming the first barrier structures 211 to be larger than that of the material forming the dielectric layer 242, the first barrier structures 211 can better block the diffusion of conductive particles in the subsequently formed conductive layer 26 compared to the dielectric layer 242, thereby avoiding the diffusion of the conductive particles in the conductive layer 26 from corners of the second trench structures 241 and reducing current leakage.

At S15, a conductive layer 26 is formed, and the conductive layer 26 fully fills the second trench structures 241, as shown in FIG. 2I.

Optionally, after forming the dielectric layer 242 and before forming the conductive layer 26, the following operation is further included.

A second barrier layer 25 is formed, and the second barrier layer 25 covers an upper surface of the dielectric layer 242, bottoms of the second trench structures 241, and sidewalls of the second trench structures 241.

Optionally, the method for forming the semiconductor structure further includes the following.

The material forming the second barrier layer 25 includes titanium nitride. With a large compactness, the titanium nitride material can better block the penetration of the conductive layer 26 into the dielectric layer 242. Moreover, with a certain electrical conductivity, the titanium nitride material can ensure the electrical conductivity of the plug wire.

Specifically, after etching part of the initial dielectric layer 24 to form the second trench structures 241, the barrier material such as titanium nitride is deposited by adopting the atomic layer deposition process or the chemical vapor deposition process on inner walls of the second trench structures 241, top surfaces of the dielectric layer 242 (i.e., the surface of the dielectric layer 242 facing away from the substrate 20), and the surfaces of the first barrier structures 211 exposed through the sidewalls of the second trench structures 241. Then, the second trench structures 241 is filled up by a physical vapor deposition process, a chemical vapor deposition process, an atomic layer deposition process, or an electroplating process to form the conductive layer 26, as shown in FIG. 21.

Optionally, the method for forming a semiconductor structure includes the following.

The dielectric layer 242 covers upper surfaces of the barrier structures 211.

Specifically, along the direction perpendicular to the substrate 20, the height of the dielectric layer 242 is larger than the height of the first barrier structures 211, thus avoiding increasing the parasitic capacitance inside the semiconductor structure and ensuring the performance stability of the semiconductor structure. A relative proportionality between the height of the dielectric layer 242 and the height of the first barrier structures 211 can be selected by those skilled in the art according to practical needs, for example according to specific materials of the first barrier structures 211. Optionally, the height of the dielectric layer 242 is more than two times the height of the first barrier structures 211.

Optionally, there are three or more first barrier structures 211 between two adjacent second trench structures 241.

Specifically, as shown in FIG. 2H, sidewalls of each of the second trench structures 241 expose sidewalls of two first barrier structures 211. There is also at least one first barrier structure 211 covered by the dielectric layer 242 between the two first barrier structures 211 exposed through the two adjacent second trench structures 241, thus better avoiding leakage between the adjacent conductive layers 26.

In other implementations, those skilled in the art may modify the pattern in the mask layer 31 so that the adjacent second trench structures 241 have and only have two first barrier structures 211 therebetween. For example, as shown in FIG. 2J, in two adjacent second trench structures 241, sidewalls of each of the second trench structures 241 expose two first barrier structures 211. There is no additional first barrier structure 211 between the two first barrier structures 211 exposed through the two adjacent second trench structures 241, such that the process is simplified.

Optionally, in a radial direction along the second trench structures 241, the width of the first barrier structures 211 is less than or equal to the width of the second barrier layer 25.

Specifically, by setting the width of the first barrier structures 211 to be less than or equal to the width of the second barrier layer 25, a spacing distance between the adjacent second trench structures 241 can be ensured without increasing the parasitic capacitance of the semiconductor structure, thus avoiding affecting characteristic dimensions of the conductive layer 26.

In order to reduce the effect of parasitic capacitance, optionally, the method for forming the semiconductor structure further includes the following.

The dielectric constant of a material forming the first barrier structures 211 is larger than the dielectric constant of a material forming the dielectric layer 242.

Optionally, the material forming the first barrier structures 211 is silicon nitride, and the material forming the dielectric layer 242 is silica.

Moreover, an implementation also provides a semiconductor structure. The semiconductor structure provided by the implementation can be formed by adopting a method for forming a semiconductor structure as shown in FIG. 1, FIG. 2A-FIG. 2J. The schematic diagram of the semiconductor structure provided in the implementation can be seen in FIG. 2I and FIG. 2J. As shown in FIG. 2I and FIG. 2J, the semiconductor structure provided in the implementation includes a substrate 20, first barrier structures 211, a dielectric layer 242 and a conductive layer 26.

The first barrier structures 211 distribute at intervals on the substrate 20. First trench structures 212 exposing the substrate 20 are provided between the adjacent first barrier structures 211.

The dielectric layer 242 fills up at least part of the first trench structures 212. The dielectric layer 242 has second trench structures 241 which expose part of the first barrier structures 211. The compactness of a material forming the first barrier structures 211 is larger than that of a material forming the dielectric layer 242.

The conductive layer 26 fills up the second trench structures 241.

Optionally, the dielectric constant of the material forming the first barrier structures 211 is larger than the dielectric constant of the material forming the dielectric layer 242.

Optionally, the material forming the first barrier structures 211 is silicon nitride, and the material forming the dielectric layer 242 is silica.

Optionally, the semiconductor structure further includes the following.

A second barrier layer 25 locates between the dielectric layer 242 and the conductive layer 26, and covers an upper surface of the dielectric layer 242, bottoms of the second trench structures 241 and sidewalls of the second trench structures 241.

Optionally, the material forming the second barrier structures 25 is titanium nitride.

Optionally, the dielectric layer 242 covers upper surfaces of the first barrier structures 211.

Specifically, along a direction perpendicular to the substrate 20, the height of the dielectric layer 242 is larger than the height of the first barrier structures 211, thus avoiding increasing the parasitic capacitance inside the semiconductor structure and ensuring the performance stability of the semiconductor structure. A relative proportionality between the height of the dielectric layer 242 and the height of the first barrier structures 211 can be selected by those skilled in the art according to practical needs, for example according to specific materials of the first barrier structures 211. Optionally, the height of the dielectric layer 242 is more than two times the height of the first barrier structures 211.

Optionally, there are three or more first barrier structures 211 between two adjacent second trench structures 241.

Specifically, as shown in FIG. 21, sidewalls of each of the second trench structures 241 expose two first barrier structures 211. There is also at least one first barrier structure 211 covered by the dielectric layer 242 between the two first barrier structures 211 exposed through the two the adjacent second trench structures 241, thus better avoiding leakage between the adjacent conductive layers 26.

In other implementations, those skilled in the art may modify the pattern in the mask layer 31 so that the adjacent second trench structures 241 have and only have two of the first barrier structures 211 therebetween. For example, as shown in FIG. 2J, the sidewalls each of the second trench structure 241 expose the two first barrier structures 211. There is no additional first barrier structure 211 between the two first barrier structures 211 exposed through the two adjacent second trench structures 241, such that the process is simplified.

Optionally, in a radial direction along the second trench structures 241, the width of the first barrier structures 211 is less than or equal to the width of the second barrier layer 25.

Specifically, by setting the width of the first barrier structure 211 to be less than or equal to the width of the second barrier layer 25, the spacing width between the adjacent second trench structures 241 can be ensured without increasing the parasitic capacitance of the semiconductor structure.

Optionally, the material of the first barrier structures 211 is one or a combination of two of SiN and SiCN. In this embodiment, the material of the first barrier structures 211 is SiN.

Specifically, the material of the first barrier structures 211 may be the same as the material of the second barrier layer 25 or different from the material of the second barrier layer 25. In the implementation, in order to further improve the stability of the conductive layer 26 and better avoid electrical leakage, the material of the first barrier structures 211 is different from the material of the second barrier layer 25. For example, the material of the first barrier structures 211 is SiN; and the material of the second barrier layer 25 is TiN. The material of the conductive layer 26 is a metal material, such as Cu or Al.

According to the method for forming the semiconductor structure and the semiconductor structure provided in the implementation, the first barrier structure is embedded in the dielectric layer, and the compactness of the material forming the first barrier structures is larger than that of the material forming the dielectric layer, which can prevent damage to the corners of the through hole during etching the dielectric layer to form a plug wire. In addition, the embedded first barrier structures prevent the diffusion of the plug wires into the dielectric layer, thereby increasing the stability of the conductive layer and thus improving the reliability of an entire device. Moreover, the embedded first barrier structures in the dielectric layer substantially improve the stability of plug wire structures with a slight increase in the parasitic capacitance while ensuring the electrical performance of the semiconductor device.

The descriptions above are only preferred implementations of this disclosure, it should be noted that for those ordinary skilled in the art, a number of improvements and embellishments can be made without departing from the principles of this disclosure, and these improvements and embellishments should also be considered as the scope of protection of this disclosure.

What is claimed is:

1. A method for forming a semiconductor structure, comprising:
providing a substrate;
forming a plurality of first barrier structures that are distributed at intervals on the substrate, first trench structures exposing the substrate being provided between the adjacent first barrier structures;
forming an initial dielectric layer, the initial dielectric layer filling up the first trench structures;
removing part of the initial dielectric layer to form a dielectric layer, the dielectric layer having second trench structures, and the second trench structures exposing part of the first barrier structures, wherein a compactness of a material forming the first barrier structures is larger than that of a material forming the dielectric layer; and
forming a conductive layer, the conductive layer filling up the second trench structures.

2. The method for forming a semiconductor structure of claim 1, wherein said forming a plurality of the first barrier structures that are distributed at intervals on the substrate comprises:
forming a first barrier layer on the substrate, the first barrier layer covering the substrate;
forming a dielectric layer on the first barrier layer, the dielectric layer having third trench structures, and projections of the third trench structures on the substrate coinciding with projections of the first trench structures on the substrate;
etching the first barrier layer by adopting the dielectric layer as a mask; and
removing the dielectric layer.

3. The method for forming a semiconductor structure of claim 2, wherein said forming a dielectric layer on the first barrier layer specifically comprises:
forming an initial mask layer on the first barrier layer, the initial mask layer covering the first barrier layer;
patterning the initial mask layer to form a mask layer, the mask layer having fourth trench structures;
forming an initial dielectric layer, the initial dielectric layer covering at least bottoms and sidewalls of the fourth trench structures; and
removing the mask layer and part of the initial dielectric layer, and remaining the initial dielectric layer covering the sidewalls of the fourth trench structures.

4. The method for forming a semiconductor structure of claim 3, wherein said forming the initial dielectric layer which covers at least bottoms and sidewalls of the fourth trench structures comprises:
forming the initial dielectric layer by atomic layer deposition.

5. The method for forming a semiconductor structure of claim 1, wherein
a dielectric constant of a material forming the first barrier structures is larger than that of a material forming the dielectric layer.

6. The method for forming a semiconductor structure of claim 5, wherein
the material forming the first barrier structures is silicon nitride, and the material forming the dielectric layer is silica.

7. The method for forming a semiconductor structure of claim 1, further comprising: after said forming the dielectric layer and prior to said forming a conductive layer,
forming a second barrier layer, the second barrier layer covering upper surface of the dielectric layer, bottoms and sidewalls of the second trench structures.

8. The method for forming a semiconductor structure of claim 7, wherein
a material forming the second barrier layer comprises titanium nitride.

9. The method for forming a semiconductor structure of claim 1, wherein
the dielectric layer covers upper surfaces of the first barrier structures.

10. A semiconductor structure, comprising:
a substrate;
first barrier structures, distributing at intervals on the substrate, first trench structures exposing the substrate being provided between the adjacent first barrier structures;
a dielectric layer, filling up at least part of the first trench structures, the dielectric layer having second trench structures and the second trench structures exposing part of the first barrier structures, wherein a compactness of a material forming the first barrier structures is larger than that of a material forming the dielectric layer; and
a conductive layer, filling up the second trench structures.

11. The semiconductor structure of claim 10, wherein a dielectric constant of the material forming the first barrier structures is larger than that of the material forming the dielectric layer.

12. The semiconductor structure of claim 11, wherein the material forming the first barrier structures is silicon nitride, and the material forming the dielectric layer is silica.

13. The semiconductor structure of claim 11, further comprising:
a second barrier layer, located between the dielectric layer and the conductive layer, and covering upper surface of the dielectric layer, bottoms of the second trench structures and sidewalls of the second trench structures.

14. The semiconductor structure of claim 13, wherein a material forming the second barrier structure is titanium nitride.

15. The semiconductor structure of claim 10, wherein the dielectric layer covers upper surfaces of the first barrier structures.
